(19) United States
(12) Patent Application Publication
(10) Pub. No.: US 2025/0255008 A1
(43) Pub. Date: Aug. 7, 2025

(54) PROTECTION DIODE AND SEMICONDUCTOR DEVICE HAVING THE SAME

(71) Applicant: Samsung Electronics Co., Ltd., Suwon-si (KR)

(72) Inventors: Wonsok LEE, Suwon-si (KR); Minhee CHO, Suwon-si (KR); Daewon HA, Suwon-si (KR)

(73) Assignee: Samsung Electronics Co., Ltd., Suwon-si (KR)

(21) Appl. No.: 19/013,528

(22) Filed: Jan. 8, 2025

(30) Foreign Application Priority Data
Feb. 2, 2024 (KR) 10-2024-0016907

(51) Int. Cl. H10D 89/60

(52) U.S. Cl. CPC H10D 89/611

(57) ABSTRACT

Provided is a protection diode for protecting a transistor from a transient voltage, the protection diode including a substrate, a lower insulation film on the substrate, an oxide semiconductor layer on the lower insulation film, a first electrode and a second electrode arranged on the oxide semiconductor layer to be horizontally spaced apart from each other and providing a Schottky contact, and an interlayer insulation film surrounding the first electrode and the second electrode on the oxide semiconductor layer, wherein the first electrode is electrically connected to a gate electrode of the transistor, and the second electrode is connected to a ground level or a certain DC level.

### CROSS-REFERENCE TO RELATED APPLICATION

This application is based on and claims priority under 35 U.S.C. § 119 to Japanese Patent Application No. 10-2024-0016907, filed on Feb. 2, 2024, in the Korean Intellectual Property Office, the disclosure of which is incorporated by reference herein in its entirety.

### BACKGROUND

The inventive concepts relate to a protection diode and a semiconductor device including the same, and more particularly, to a protection diode including an oxide semiconductor and a semiconductor device including the protection diode.

Semiconductor devices are used for various purposes in electronic products, and the reliability of these semiconductor devices may be affected by various factors. One of such factors may be the occurrence of an unwanted transient voltage during the operation of a semiconductor device. When a transient voltage occurs, a gate dielectric film of a semiconductor device may be destroyed, which may cause performance degradation of the semiconductor device. Therefore, to protect semiconductor devices from such transient voltage, a protection diode may be used.

### SUMMARY

The inventive concepts provide a protection diode including an oxide semiconductor to prevent and/or mitigate destruction of a gate dielectric film of a semiconductor device by preventing application of a transient voltage to the semiconductor device and/or reducing the magnitude thereof.

In addition, the technical goals to be achieved by the inventive concepts are not limited to the technical goals mentioned above, and other technical goals may be clearly understood by one of ordinary skill in the art from the following descriptions.

According to an aspect of the inventive concepts, there is provided a protection diode for protecting a transistor from a transient voltage, the protection diode including a semiconductor layer on the lower insulation film such that the lower insulation film is between the semiconductor layer and the substrate; a first electrode and a second electrode on the semiconductor layer such that the first electrode and the second electrode are horizontally spaced apart from each other and provide a Schottky contact; and an interlayer insulation film on the semiconductor layer and surrounding the first electrode and the second electrode, wherein the first electrode is electrically connected to a gate electrode of the transistor, and the second electrode is connected to a ground level or a certain DC level.

According to another aspect of the inventive concepts, there is provided a protection diode for protecting a transistor from a transient voltage, the protection diode including semiconductor layer on the lower insulation film such that the lower insulation film is between the semiconductor layer and the substrate; N electrodes (N is an integer greater than or equal to 3) on the semiconductor layer, the N electrodes horizontally spaced apart from one another and providing at least one Schottky contact; and an interlayer insulation film on the semiconductor layer and surrounding the N electrodes, wherein a first electrode, located at one end of the N electrodes, is electrically connected to a gate electrode of the transistor, and a second electrode, located at another end of the N electrodes, is connected to a ground level or a certain DC level.

According to another aspect of the inventive concepts, there is provided a semiconductor device including a channel region on a substrate; a gate structure on the channel region and comprising a gate dielectric, a gate electrode, and a gate capping film that are sequentially stacked, and further comprising gate spacers on sidewalls of the gate dielectric, the gate electrode, and the gate capping film, and a gate contact contacting the gate electrode; source/drain regions on both sides of the channel region; source/drain contacts electrically contacting the source/drain regions; and a protection diode configured to protect the gate dielectric from a transient voltage, wherein the protection diode comprises a lower insulation film on the substrate, a semiconductor layer on the lower insulation film such that the lower insulation film is between the semiconductor layer and the substrate, a first electrode and a second electrode on the semiconductor layer such that the first electrode and the second electrode are horizontally spaced apart from each other and provide a Schottky contact, and an interlayer insulation film on the semiconductor layer and surrounding the first electrode and the second electrode on the semiconductor layer.

### BRIEF DESCRIPTION OF THE DRAWINGS

Embodiments of the inventive concepts will be more clearly understood from the following detailed description taken in conjunction with the accompanying drawings in which:

FIG. 1 is a circuit diagram of a protection diode according to at least one embodiment;

FIG. 2 is a cross-sectional view of components of a protection diode in a portion AA of FIG. 1;

FIG. 3 is an energy band diagram of a material constituting the protection diode of FIG. 2;

FIG. 4 is a cross-sectional view showing components of a protection diode according to another embodiment;

FIG. 5 is a circuit diagram of a protection diode according to at least one embodiment;

FIGS. 6 and 7 are cross-sectional views of components of protection diodes in a portion BB of FIG. 5;

FIG. 8 is a cross-sectional view of components of a protection diode and a semiconductor device including the same, according to at least one embodiment;

FIG. 9 is a flowchart of a method of manufacturing a protection diode, according to at least one embodiment; and

FIGS. 10 to 16 are cross-sectional views showing a method of manufacturing a protection diode according to at least one embodiment according to a process sequence.

### DETAILED DESCRIPTION OF THE EMBODIMENTS

Hereinafter, preferred embodiments of the present inventive concepts will be described with reference to the accompanying drawings. Hereinafter, it can be understood that spatially relative terms, such as ‘on,’ ‘upper,’ ‘upper portion,’ ‘upper surface,’ ‘below,’ ‘lower,’ ‘lower portion,’ ‘lower surface,’ ‘side surface,’ and/or the like, may be denoted by reference numerals and refer the spatial relationship between elements illustrated in the drawings, except where otherwise indicated. Therefore, it will also be understood that such spatially relative terms are intended to encompass different orientations of the device in use or operation in addition to the orientation depicted in the figures, and that the device may be otherwise oriented (rotated 90 degrees or at other orientations) and the spatially relative terms used herein interpreted accordingly.

Additionally, when the terms “about” or “substantially” are used in this specification in connection with a numerical value and/or geometric terms, it is intended that the associated numerical value includes a manufacturing tolerance (e.g., ±10%) around the stated numerical value. Further, regardless of whether numerical values and/or geometric terms are modified as “about” or “substantially,” it will be understood that these values should be construed as including a manufacturing or operational tolerance (e.g., +10%) around the stated numerical values and/or geometry. Additionally, whenever a range of values is enumerated, the range includes all values within the range as if recorded explicitly clearly, and may further include the boundaries of the range. Accordingly, of “X” to “Y” provides a range including all values between X and Y, including X and Y.

Additionally, ordinal numbers such as “first,” “second,” “third,” or the like may be used as labels for specific elements, steps, operations, directions, or the like to distinguish various elements, steps, operations, directions, or the like from each other. Terms that may not be described using “first,” “second,” or the like in the specification may still be referred to as “first” or “second” in the claims. Additionally, terms referenced by a particular ordinal number (e.g., “first” in a particular claim) may be described elsewhere with a different ordinal number (e.g., “second” in the specification or another claim).

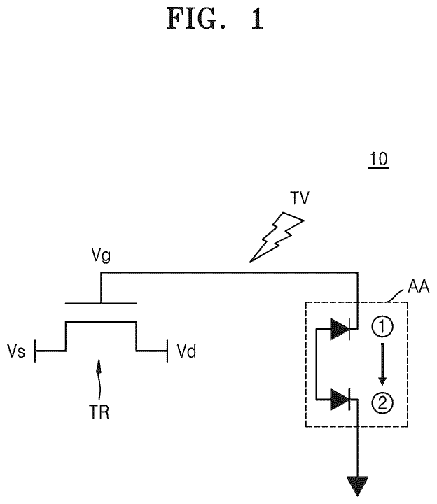

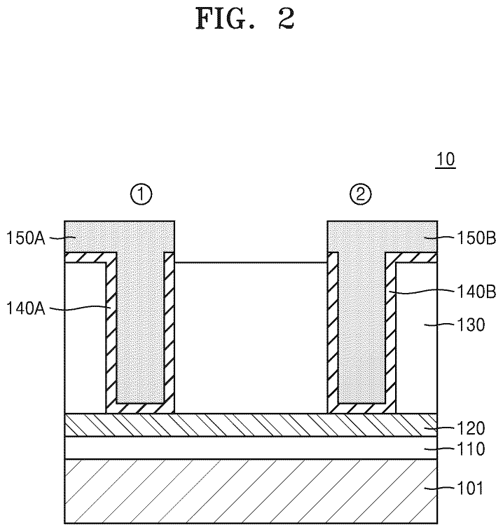

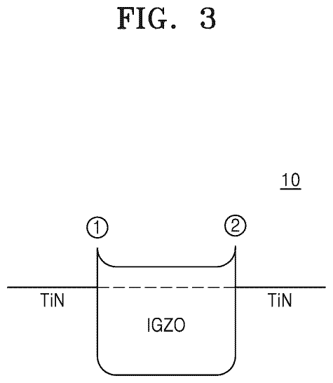

FIG. 1 is a circuit diagram of a protection diode according to at least one embodiment. FIG. 2 is a cross-sectional view of components of a protection diode in a portion AA of FIG. 1. FIG. 3 is an energy band diagram of a material constituting the protection diode of FIG. 2.

Referring to FIGS. 1 to 3 together, a protection diode 10 according to at least one embodiment may include a substrate 101, a lower insulation film 110, a semiconductor layer 120, an interlayer insulation film 130, first electrode 140A and 150A, and second electrode 140B and 150B.

According to some embodiments, the substrate 101 may be a semiconductor substrate and include silicon (Si), e.g., monocrystalline Si, polycrystalline Si, and/or amorphous Si. According to other embodiments, the substrate 101 may include at least one selected from among Ge, SiGe, SiC, GaAs, InAs, and InP. According to some embodiments, the substrate 101 may include a conductive region, e.g., a well doped with an impurity or a structure doped with an impurity.

According to other embodiments, the substrate 101 may be a growth substrate and may, therefore, utilize an insulation material, a conductive material, and/or a semiconductor material such as sapphire, Si, SiC, MgAl₂O₄, MgO, LiAlO₂, LiGaO₂, GaN, etc. When the substrate 101 includes sapphire, the substrate 101 may include crystals that are electrically insulating and have hexa-Rhombo symmetry.

The lower insulation film 110 may be disposed on the substrate 101. The lower insulation film 110 may include insulating materials, such as silicon oxide, silicon oxynitride, aluminum oxide, a high-k material having a higher dielectric constant than silicon oxide, and/or a combination thereof. The high-k material may include a metal oxide or a metal oxynitride with a dielectric constant greater than the dielectric constant of silicon oxide. For example, the high-k material that may constitute the lower insulation film 110 may include, but is not limited to, HfO₂, HfSiO, HfSiON, HfTaO, HfTiO, HfZrO, zirconium oxide, aluminum oxide, and/or a combination thereof.

According to some embodiments, the lower insulation film 110 may function as a buffer layer to relieve stress caused by a difference between lattice constants of a material constituting the substrate 101 and a material constituting the semiconductor layer 120 and/or, the lower insulation film 110 may function as a barrier film to mitigate and/or prevent diffusion of impurities from the substrate 101 into the semiconductor layer 120 and to mitigate and/or prevent a current flowing within the semiconductor layer 120 from leaking into the substrate 101.

The semiconductor layer 120 may be disposed on the lower insulation film 110. The semiconductor layer 120 may include a conductive oxide, e.g., a homologous oxide. Here, the homologous oxide may refer to a material having the chemical formula of RAO₃(MO)ₙ(R denotes at least one element selected from among Sc, Yb, Lu, and In; A denotes at least one element selected from among Ga, Al, Fe, and In; M denotes at least one element selected from Zn and Mg; and n is an integer). However, elements R, A, and M that may be included in the homologous oxide are not limited to the above-stated elements.

For example, according to some embodiments, the semiconductor layer 120 may include an oxide semiconductor, for example, at least one of InGaZnOₓ (i.e., InGaZnO or IGZO), InGaOₓ (i.e., InGaO or IGO), InSnGaOₓ (i.e., InSnGaO or ITGO), InGaSiOₓ (i.e., InGaSiO), InSnZnOₓ (i.e., InSnZnO or ITZO), InZnOₓ (i.e., InZnO or IZO), SnO₂, HfInZnOₓ (i.e., HfInZn or HIZO), YbGaO₃(ZnO)₅ (i.e., YGZO), and/or a combination thereof, but is not limited thereto.

According to other embodiments, the materials constituting the semiconductor layer 120 may include a 2-dimensional (2D) material. The 2D material may include, for example, MoS, ReS, WS, MoSe, HfSe, InSe, GaSe, WSe, and/or the like but is not limited thereto. Therefore, the semiconductor layer 120 may be referred to as a compound semiconductor layer or an oxide semiconductor layer.

The interlayer insulation film 130 may be disposed on the semiconductor layer 120. The interlayer insulation film 130 may include an insulating material, such as silicon nitride, silicon oxide, silicon oxynitride, a TEOS film, and/or an ultra-low-k (ULK) film having an ultra-low dielectric constant from about 2.2 to about 2.4.

The first electrode 140A and 150A and the second electrode 140B and 150B may be arranged to penetrate through the interlayer insulation film 130 and contact the semiconductor layer 120.

The first electrode 140A and 150A and the second electrode 140B and 150B may each be formed in a double-layer structure including a first metal line 150A and a second metal line 150B and a first metal barrier film 140A and a second metal barrier film 140B surrounding side surfaces and bottom surfaces of the first metal line 150A and the second metal line 150B. In other words, the first metal barrier film 140A and the second metal barrier film 140B may be first arranged to contact the semiconductor layer 120 and the interlayer insulation film 130, and then the first metal line 150A and the second metal line 150B may be arranged to cover the first metal barrier film 140A and the second metal barrier film 140B such that the first metal barrier film 140A and the second metal barrier film 140B separate the first metal line 150A and the second metal line 150B from the semiconductor layer 120.

According to some embodiments, the first metal barrier film 140A and the second metal barrier film 140B may each include, for example, titanium (Ti), tantalum (Ta), ruthenium (Ru), titanium nitride (TiN), tantalum nitride (TaN), and/or a combination thereof. Also, the first metal line 150A and the second metal line 150B include, for example, at least one of cobalt (Co), tungsten (W), molybdenum (Mo), lutetium (Lu), platinum (Pt), palladium (Pd), nickel (Ni), ruthenium (Ru), copper (Cu), aluminum (Al), silicides thereof, and/or alloys thereof, but is not limited thereto. In some embodiments, the first metal barrier film 140A and the second metal barrier film 140B may be omitted, and the first electrode 140A and 150A and the second electrode 140B and 150B may each be formed in a single-layer structure including the first metal line 150A and the second metal line 150B.

According to some embodiments, the first electrode 140A and 150A may include the same material and the second electrode 140B and 150B may include the same material. For example, the first metal barrier film 140A and the second metal barrier film 140B and the first metal line 150A and the second metal line 150B may include different materials, but the first metal barrier film 140A and the second metal barrier film 140B may include the same material, and the first metal line 150A and the second metal line 150B may include the same material.

Transistors TR are used in electronic products for various purposes. For example, in a transistor TR, a gate voltage Vg may be provided to a gate electrode, a source voltage Vs may be provided to a source region, and a drain voltage Vd may be provided to a drain region. The reliability of such a transistors TR may be affected by various factors.

One of the various factors may be the occurrence of an unwanted transient voltage TV during the operation of the transistor TR. When a transient voltage TV occurs, a gate dielectric film of the transistor TR may be degraded and/or destroyed, which may cause performance degradation of the transistor TR.

Therefore, to protect the transistor TR from such transient voltage TV, a protection diode 10 may be used. Recently, the transistor TR may include an semiconductor in the form of, for example, an oxide thin-film transistor (TFT). To protect the transistor TR, the protection diode 10 containing an semiconductor layer.

In the protection diode 10 according to the inventive concepts, the semiconductor layer 120 may serve as a cathode electrode, and the first electrode 140A and 150A and the second electrode 140B and 150B may serve as anode electrodes. In other words, the semiconductor layer 120 and the first electrode 140A and 150A may form a Schottky contact and operate as a first Schottky barrier \textcircled{1}.

Also, the semiconductor layer 120 and the second electrode 140B and 150B may form another Schottky contact and operate as a second Schottky barrier \textcircled{2}. For example, the energy band diagram in the case where the first electrode 140A and 150A and the second electrode 140B and 150B include titanium nitride (TiN) and the semiconductor layer 120 includes IGZO is as shown in FIG. 3.

To protect the transistor TR from a transient voltage, the protection diode 10 according to the inventive concepts may be configured, such that the first electrode 140A and 150A constituting the first Schottky barrier \textcircled{1} is electrically connected to the gate electrode of the transistor TR, and the second electrode 140B and 150B constituting the second Schottky barrier \textcircled{2} is connected to a ground level and/or a certain DC level.

Here, the certain DC level may vary according to the type of transistor TR and may refer to a particular DC level (e.g., 1V, 2V, 3V, etc.) different from the ground level (e.g., 0V). In other words, the certain DC level may be a value that varies according to the type of transistor TR.

In the protection diode 10 according to the inventive concepts, the first electrode 140A and 150A constituting the first Schottky barrier \textcircled{1} and the second electrode 140B and 150B constituting the second Schottky barrier \textcircled{2} may be arranged to share one semiconductor layer 120 with each other. Therefore, the first Schottky barrier \textcircled{1} and the second Schottky barrier \textcircled{2} may be configured to be connected to each other in series.

In other words, the protection diode 10 according to at least one embodiment may use the first Schottky barrier \textcircled{1} and the second Schottky barrier \textcircled{2} sharing the semiconductor layer 120 to prevent an unwanted transient voltage TV from being applied to the transistor TR and/or to reduce the magnitude of the unwanted transient voltage TV being applied to the transistor TR.

Ultimately, it is possible to prevent the gate dielectric film of the transistor TR from being destroyed by connecting the protection diode 10 according to at least one embodiment to the gate electrode of the transistor TR. Therefore, performance degradation of the transistor TR may be prevented and/or mitigated, and thus the reliability and the quality of an electronic product may be improved.

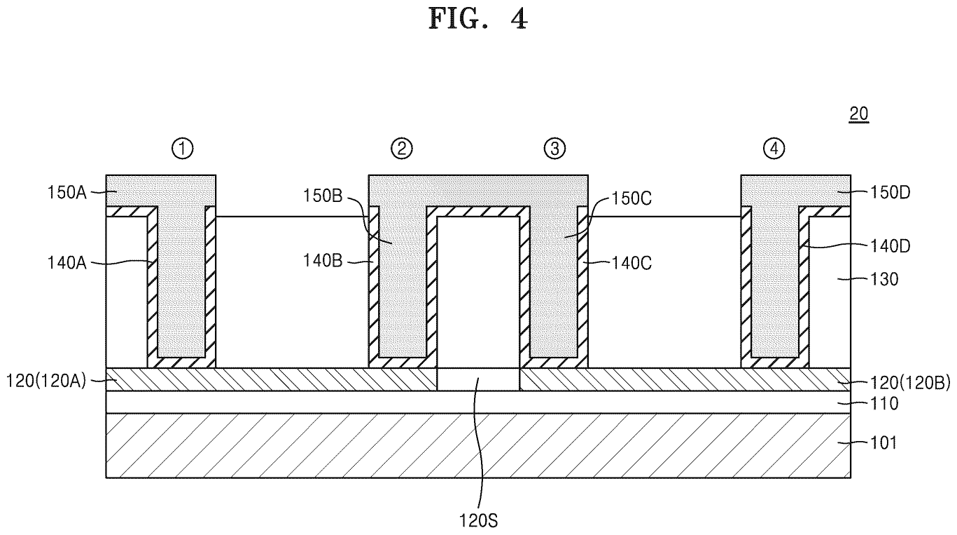

FIG. 4 is a cross-sectional view showing components of a protection diode according to another embodiment.

Most of the components constituting a protection diode 20 described below and materials constituting the components may be substantially the same as and/or substantially similar to those described in FIGS. 1 to 3 above. Therefore, for convenience of explanation, descriptions below will focus on differences from the protection diode 10 described above.

Referring to FIG. 4, the protection diode 20 according to at least one embodiment may include the substrate 101, the lower insulation film 110, the semiconductor layer 120, the interlayer insulation film 130, the first electrode 140A and 150A, the second electrode 140B and 150B, third electrode 140C and 150C, and fourth electrode 140D and 150D.

In the protection diode 20 according to the present embodiment, N electrodes (N is an integer equal to or greater than 3) that are spaced apart from one another in a horizontal direction and provide a Schottky contact may be arranged on the semiconductor layer 120. Here, the case where N=4 is described as an example, but the inventive concepts is not limited thereto.

As shown in FIG. 4, the protection diode 20 may include the first electrode 140A and 150A, the second electrode 140B and 150B, the third electrode 140C and 150C, and the fourth electrode 140D and 150D in a horizontal direction.

In the protection diode 20, the semiconductor layer 120 may include a first semiconductor piece 120A, a second semiconductor piece 120B, and a space insulation layer 120S disposed therebetween. In other words, the semiconductor layer 120 includes semiconductor pieces separated by the space insulation layer 120S, and two of the N electrodes may be arranged on each of the semiconductor pieces.

As shown in FIG. 4, the first semiconductor piece 120A and the first electrode 140A and 150A may operate as the first Schottky barrier \textcircled{1}, and the first semiconductor piece 120A and the second electrode 140B and 150B may operate as the second Schottky barrier \textcircled{2}.

Also, the second semiconductor piece 120B and the third electrode 140C and 150C may operate as a third Schottky barrier \textcircled{3}, and the second semiconductor piece 120B and the fourth electrode 140D and 150D may operate as a fourth Schottky barrier \textcircled{4}.

To protect the transistor TR (refer to FIG. 1) from a transient voltage, the protection diode 20 according to the present embodiments may be configured, such that the first electrode 140A and 150A located at one end of the N electrodes are electrically connected to the gate electrode of the transistor TR, and the fourth electrode 140D and 150D located at the other end of the N electrodes are connected to the ground level or a certain DC level.

Here, the certain DC level may vary according to the type of transistor TR and may refer to a particular DC level (e.g., 1V, 2V, 3V, etc.) different from the ground level (e.g., 0V). In other words, the certain DC level may be a value that varies according to the type of transistor TR.

As shown in FIG. 4, except for the first electrode 140A and 150A and the fourth electrode 140D and 150D from among the N electrodes, the second electrode 140B and 150B and the third electrode 140C and 150C, which are pairs of electrodes adjacent to each other, may be electrically connected to each other through horizontal metal lines 150B and 150C on the interlayer insulation film 130. Therefore, first to fourth Schottky barriers \textcircled{1}, \textcircled{2}, \textcircled{3}, \textcircled{4} may be configured to be connected to one another in series.

In this regard, when the first to fourth Schottky barriers \textcircled{1}, \textcircled{2}, \textcircled{3}, \textcircled{4} are connected to one another in series, the protection diode 20 may adjust a clamping voltage.

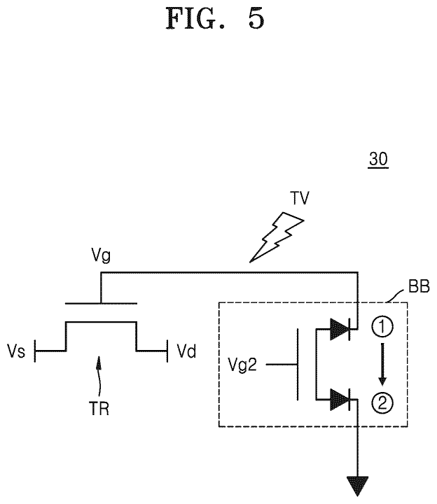

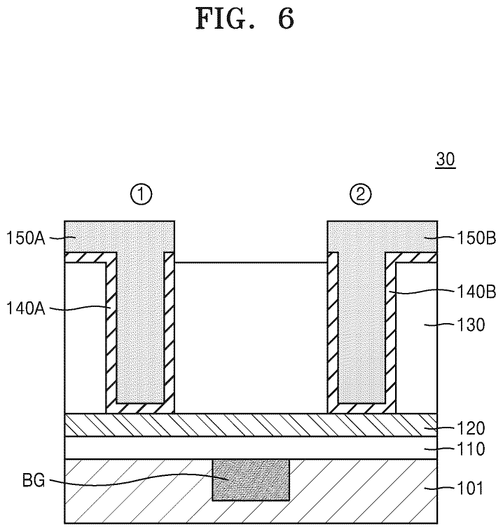

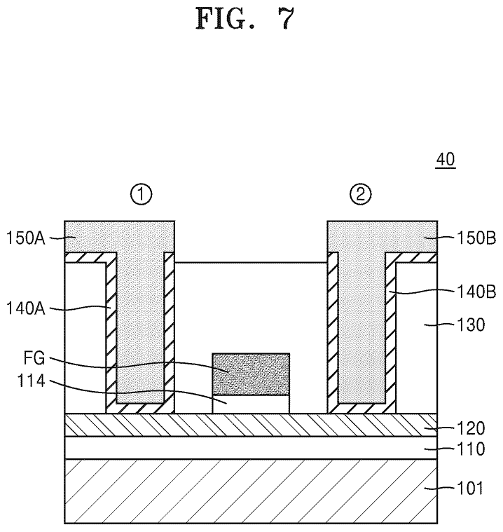

FIG. 5 is a circuit diagram of a protection diode according to at least one embodiment. FIGS. 6 and 7 are cross-sectional views of components of protection diodes in a portion BB of FIG. 5.

Most of the components constituting protection diodes 30 and 40 described below and materials constituting the components may be substantially the same as and/or substantially similar to those described in FIGS. 1 to 3 above. Therefore, for convenience of explanation, descriptions below will focus on differences from the protection diode 10 described above.

Referring to FIGS. 5 and 6 together, a protection diode 30 according to at least one embodiment may include the substrate 101, the lower insulation film 110, the semiconductor layer 120, the interlayer insulation film 130, the first electrode 140A and 150A, the second electrode 140B and 150B, and a back gate BG.

The protection diode 30 according to the present embodiment may further include a gate structure disposed between the first electrode 140A and 150A and the second electrode 140B and 150B in the horizontal direction, and the gate structure may be a back gate structure 110 and a back gate BG disposed below the lower insulation film 110. Here, the lower insulation film 110 may operate as a back gate dielectric film.

By using the back gate structure 110 and BG, the internal resistance of the semiconductor layer 120 may be lowered according to a second gate voltage Vg2 to allow a current to flow relatively well inside the semiconductor layer 120, or the operation of the protection diode 30 may be controlled to be on and off according to the second gate voltage Vg2.

Referring to FIGS. 5 and 7 together, a protection diode 40 according to at least one embodiment may include the substrate 101, the lower insulation film 110, the semiconductor layer 120, the interlayer insulation film 130, the first electrode 140A and 150A, the second electrode 140B and 150B, a front gate dielectric film 114, and a front gate FG.

The protection diode 40 according to the present embodiment may further include a gate structure disposed between the first electrode 140A and 150A and the second electrode 140B and 150B in the horizontal direction, and the gate structure may be a front gate structure 114 and FG disposed above the lower insulation film 110.

By using the front gate structure 114 and FG, the internal resistance of the semiconductor layer 120 may be lowered according to the second gate voltage Vg2 to a current to flow relatively well inside the semiconductor layer 120, or the operation of the protection diode 40 may be controlled to be on and off according to the second gate voltage Vg2.

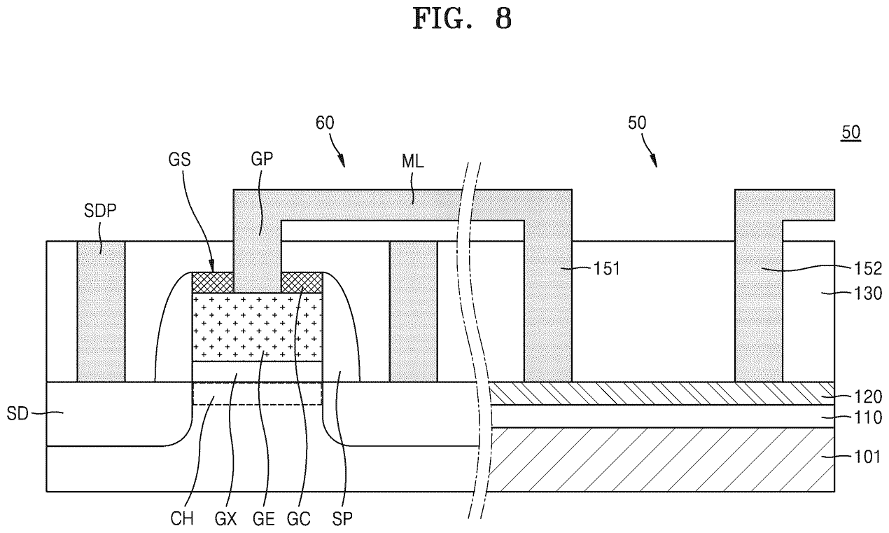

FIG. 8 is a cross-sectional view of components of a protection diode and a semiconductor device including the same, according to at least one embodiment.

Most of the components constituting a protection diode 50 described below and materials constituting the components may be substantially the same as and/or substantially similar to those described in FIGS. 1 to 3 above. Therefore, for convenience of explanation, descriptions below will focus on differences from the protection diode 10 described above.

Referring to FIG. 8, the protection diode 50 according to at least one embodiment may be disposed to be electrically connected to a semiconductor device 60.

The semiconductor device 60 according to the present embodiment may include a channel region CH and a source/drain region SD that are arranged in the substrate 101 and may include a gate structure GS, a source/drain contact SDP, and a gate contact GP that are arranged on the substrate 101.

Here, source/drain regions SD may be arranged on both sides of the channel region CH. The source/drain contact SDP may be disposed to contact the source/drain region SD. The gate structure GS may include a gate dielectric film GX, a gate electrode GE, a gate capping layer GC, and a gate spacer SP. The gate contact GP may be disposed to contact the gate electrode GE. The gate contact GP may be disposed through the gate capping layer GC.

The protection diode 50 according to the present embodiment may include the substrate 101, the lower insulation film 110, the semiconductor layer 120, the interlayer insulation film 130, a first electrode 151, and a second electrode 152. The first electrode 151 and the second electrode 152 may correspond to the first electrode 140A and 150A and the second electrode 140B and 150B described above from which the first metal barrier film 140A and the second metal barrier film 140B are removed.

Here, the gate contact GP and the first electrode 151 may be electrically connected to a metal wire ML. According to some embodiments, the channel region CH may include a material substantially identical to that constituting the semiconductor layer 120. In other words, although not shown, the channel region CH may include, for example, InGaZnOₓ (i.e., IGZO), InGaSiOₓ, InSnZnOₓ (i.e., ITZO), InZnOₓ (i.e., IZO), SnO₂, HfInZnOₓ (i.e., HIZO), YbGaO₃(ZnO)₅ (i.e., YGZO), and/or a combination thereof, but is not limited thereto.

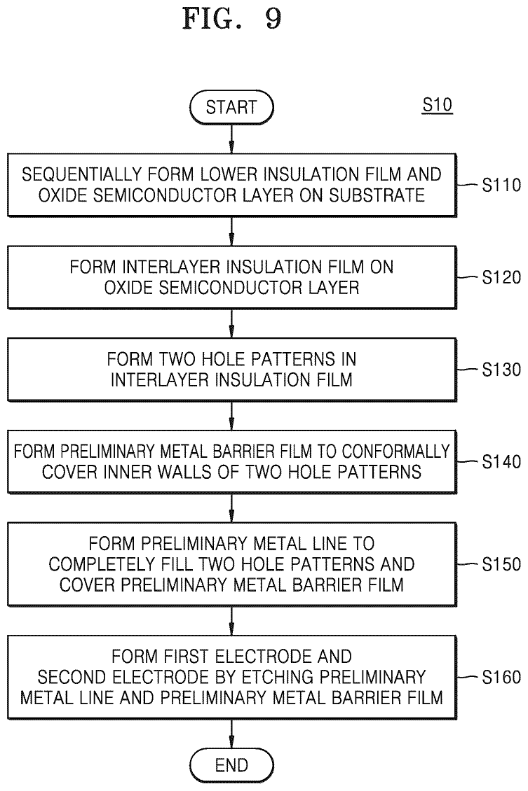

FIG. 9 is a flowchart of a method of manufacturing a protection diode, according to at least one embodiment.

Referring to FIG. 9, a method S10 of manufacturing a protection diode may include operations S110 to S190.

In a certain embodiment that may be implemented otherwise, particular operations may be performed in an order different from that described below. For example, two successively described operations may be performed substantially and simultaneously or may be performed in an order opposite to the order described below.

The method S10 of manufacturing a protection diode according to the inventive concepts may include operation S110 of sequentially forming a lower interlayer insulation film and a semiconductor (e.g., an oxide semiconductor) layer on a substrate, operation S120 of forming an interlayer insulation film on the semiconductor layer, operation S130 of forming two hole patterns in the interlayer insulation film, operation S140 of forming a preliminary metal barrier film to conformally cover inner walls of the two hole patterns, operation S150 of forming a preliminary metal line to completely fill the two hole patterns and cover the preliminary metal barrier film, and operation S160 of forming a first electrode and a second electrode by etching the preliminary metal line and the preliminary metal barrier film.

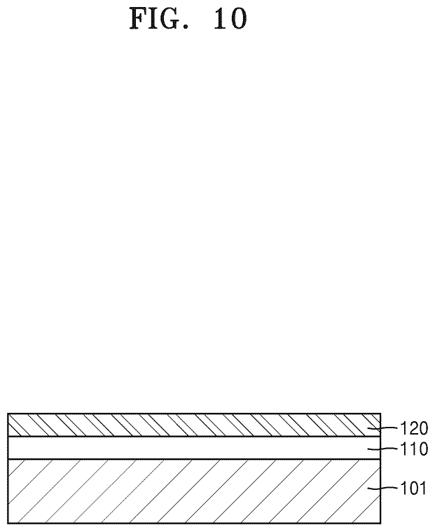

The technical features of operations S110 to S160 are described below in detail with reference to FIGS. 10 to 16.

FIGS. 10 to 16 are cross-sectional views showing a method of manufacturing a protection diode according to at least one embodiment according to a process sequence.

Referring to FIG. 10, the lower insulation film 110 may be formed on the substrate 101.

The lower insulation film 110 may include silicon oxide, silicon oxynitride, aluminum oxide, a high-k material having a higher dielectric constant than silicon oxide, and/or a combination thereof.

The lower insulation film 110 may be formed through a chemical vapor deposition (CVD) process, a thermal oxidation process, or an atomic layer deposition (ALD) process, but is not limited thereto.

Next, the semiconductor layer 120 may be formed on the lower insulation film 110. The semiconductor layer 120 may include a conductive oxide, e.g., a homologous oxide.

The semiconductor layer 120 may be formed through a physical vapor deposition (PVD) process, a pulsed laser deposition (PLD) process, a CVD process, or an ALD process, but is not limited thereto.

Optionally, the semiconductor layer 120 may be doped with at least one impurity selected from among fluorine (F), hydrogen (H), nitrogen (N), magnesium (Mg), yttrium (Y), ruthenium (Ru), and arsenic (As). For example, to dope at least one impurity into the semiconductor layer 120, the impurity may be doped in-situ during a process of forming the semiconductor layer 120 or the impurity may be implanted after formation of the semiconductor layer 120.

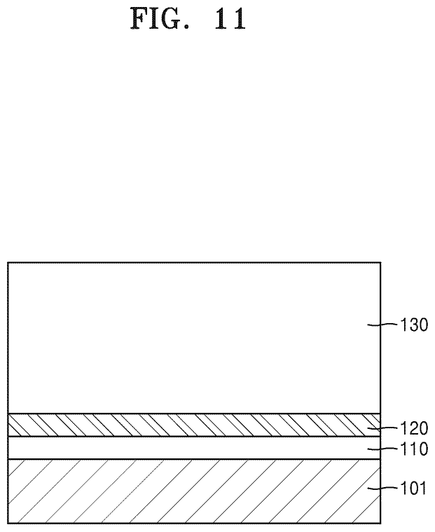

Referring to FIG. 11, the interlayer insulation film 130 may be formed on the semiconductor layer 120.

The interlayer insulation film 130 may include silicon nitride, silicon oxide, silicon oxynitride, a TEOS film, or an ultra-low-k (ULK) film having an ultra-low dielectric constant from about 2.2 to about 2.4. The interlayer insulation film 130 may be formed to have a relatively large thickness compared to the lower insulation film 110 and the semiconductor layer 120.

The interlayer insulation film 130 may be formed through a CVD process or a PVD process, but is not limited thereto.

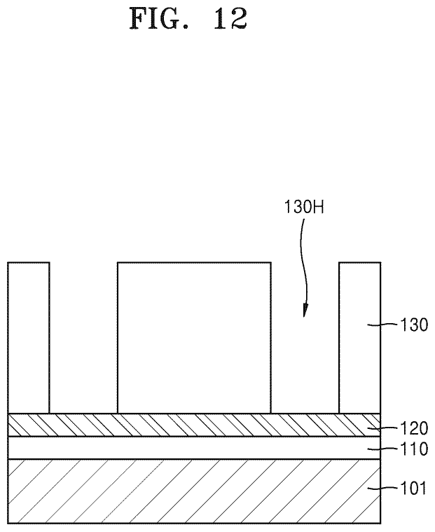

Referring to FIG. 12, a first mask pattern (not shown) may be formed on the interlayer insulation film 130, and two hole patterns 130H penetrating through the interlayer insulation film 130 and exposing the top surface of the semiconductor layer 120 may be formed by using the first mask pattern as an etching mask.

The two hole patterns 130H may have the same horizontal width and the same vertical height. Although the drawings show that the two hole patterns 130H have sidewalls perpendicular to the top surface of the semiconductor layer 120, the two hole patterns 130H may also have inclined sidewalls due to the characteristics of a dry etching process.

Next, the first mask pattern may be removed through an ashing process and/or a stripping process.

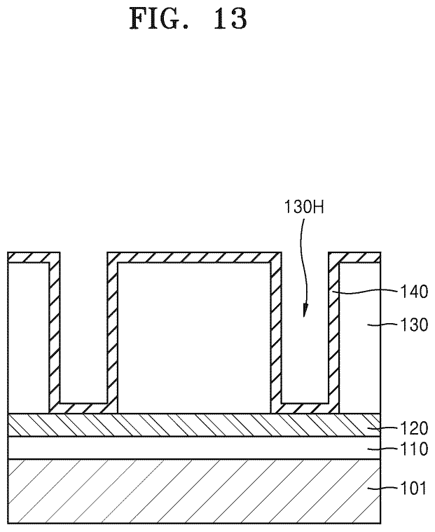

Referring to FIG. 13, a preliminary metal barrier film 140 may be formed on the interlayer insulation film 130 to conformally cover the inner walls of the two hole patterns 130H.

The preliminary metal barrier film 140 may include, for example, titanium (Ti), tantalum (Ta), ruthenium (Ru), titanium nitride (TiN), tantalum nitride (TaN), or a combination thereof.

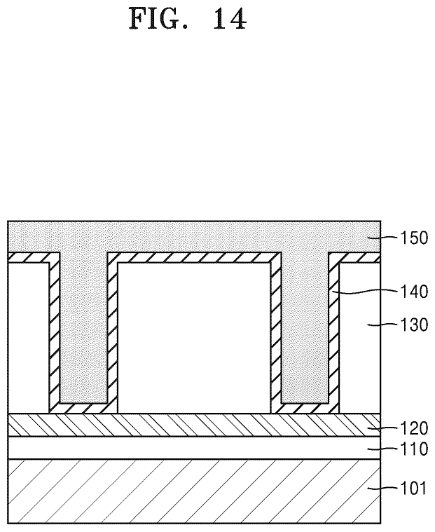

Referring to FIG. 14, a preliminary metal line 150 may be formed to completely fill the two hole patterns 130H (refer to FIG. 13) and cover the preliminary metal barrier film 140.

The preliminary metal line 150 may include at least one of, for example, cobalt (Co), tungsten (W), nickel (Ni), ruthenium (Ru), copper (Cu), aluminum (Al), silicides thereof, or alloys thereof.

Therefore, the preliminary metal line 150 may not directly contact the semiconductor layer 120 and the interlayer insulation film 130.

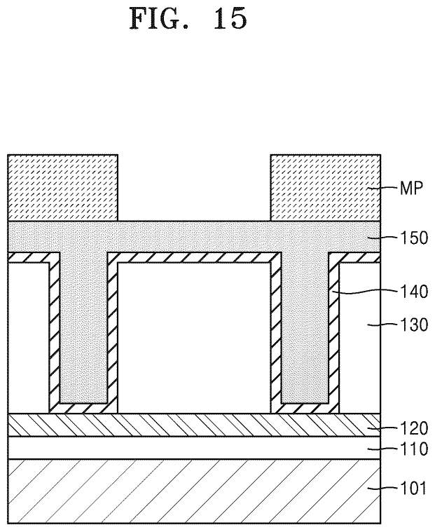

Referring to FIG. 15, a second mask pattern MP may be formed on the preliminary metal line 150.

The second mask pattern MP may be a photoresist pattern. The second mask pattern MP may be formed to have a desired pattern through an exposure process and a development process.

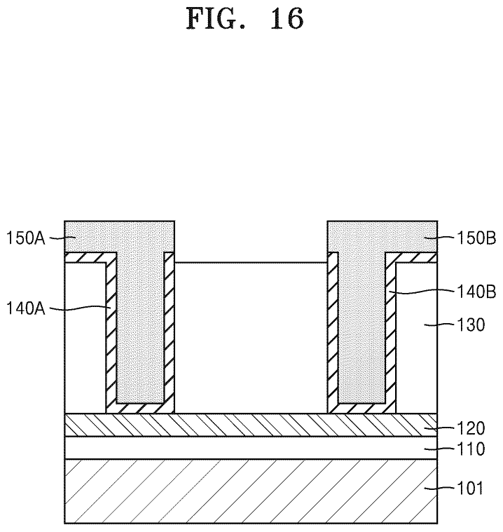

Referring to FIG. 16, the first electrode 140A and 150A and the second electrode 140B and 150B may be formed by sequentially etching the preliminary metal line 150 (refer to FIG. 15) and the preliminary metal barrier film 140 (refer to FIG. 15) by using the second mask pattern MP (refer to FIG. 15) as an etching mask.

The first electrode 140A and 150A and the second electrode 140B and 150B may be formed to penetrate through the interlayer insulation film 130 and contact the semiconductor layer 120.

The first electrode 140A and 150A and the second electrode 140B and 150B may each be formed in a double-layer structure including a first metal line 150A and a second metal line 150B and a first metal barrier film 140A and a second metal barrier film 140B surrounding side surfaces and bottom surfaces of the first metal line 150A and the second metal line 150B.

Next, the protection diode 10 shown in FIG. 2 may be completed by removing the second mask pattern MP through an ashing process and a stripping process.

While the inventive concepts have been particularly shown and described with reference to embodiments thereof, it will be understood that various changes in form and details may be made therein without departing from the spirit and scope of the following claims.

What is claimed is:

1. A protection diode configured to protect a transistor from a transient voltage, the protection diode comprising:
a substrate;
a lower insulation film on the substrate;
a semiconductor layer on the lower insulation film such that the lower insulation film is between the semiconductor layer and the substrate;
a first electrode and a second electrode on the semiconductor layer such that the first electrode and the second electrode are horizontally spaced apart from each other and provide a Schottky contact; and
an interlayer insulation film on the semiconductor layer and surrounding the first electrode and the second electrode,
wherein the first electrode is electrically connected to a gate electrode of the transistor, and
the second electrode is connected to a ground level or a certain DC level.

2. The protection diode of claim 1, wherein the first electrode and the second electrode share the semiconductor layer.

3. The protection diode of claim 1, wherein the semiconductor layer comprises an oxide semiconductor of at least one of InGaZnO, InGaO, InSnGaO, InZnO, or InSnZnO.

4. The protection diode of claim 1, wherein each of the first electrode and the second electrode comprises at least one of TiN, W, Mo, Lu, Ni, Pt, or Pd, and
the first electrode and the second electrode comprise a same material.

5. The protection diode of claim 1, wherein each of the first electrode and the second electrode comprises:
a metal barrier film in contact with the semiconductor layer and the interlayer insulation film; and
a metal line on the metal barrier film such that the metal barrier film is between the metal line and the semiconductor layer and between the metal line and the interlayer insulation film, and
wherein the metal barrier film and the metal line comprise different materials.

6. The protection diode of claim 1, wherein the semiconductor layer and the first electrode constitute a first Schottky barrier, and
the semiconductor layer and the second electrode constitute a second Schottky barrier, and
wherein the Schottky contact includes the first Schottky barrier and the second Schottky barrier.

7. The protection diode of claim 6, wherein the first Schottky barrier and the second Schottky barrier are connected to each other in series.

8. The protection diode of claim 7, further comprising:
a gate structure between the first electrode and the second electrode in a horizontal direction.

9. The protection diode of claim 8, wherein the gate structure comprises a back gate structure such that the gate structure is on a surface of the lower insulation film opposite to the first electrode and the second electrode.

10. The protection diode of claim 8, wherein the gate structure comprises a front gate structure such that the gate structure is on a same surface of the semiconductor layer as the first electrode and the second electrode.

11. A protection diode configured to protect a transistor from a transient voltage, the protection diode comprising:
a substrate;
a lower insulation film on the substrate;
a semiconductor layer on the lower insulation film such that the lower insulation film is between the semiconductor layer and the substrate;
N electrodes (N is an integer greater than or equal to 3) on the semiconductor layer, the N electrodes horizontally spaced apart from one another and providing at least one Schottky contact; and
an interlayer insulation film on the semiconductor layer and surrounding the N electrodes,
wherein a first electrode, located at one end of the N electrodes, is electrically connected to a gate electrode of the transistor, and
a second electrode, located at another end of the N electrodes, is connected to a ground level or a certain DC level.

12. The protection diode of claim 11, wherein,
N is greater than or equal to 4, and
a pair of adjacent electrodes, of the N electrodes excluding the first electrode and the second electrode, are electrically connected to each other through a horizontal metal line on the interlayer insulation film.

13. The protection diode of claim 12, further comprising:
a space insulation layer that separates the semiconductor layer into semiconductor pieces, the space insulation layer included in a region that overlaps the horizontal metal line in a vertical direction.

14. The protection diode of claim 13, wherein
the semiconductor layer comprises the semiconductor pieces separated by the space insulation layer, and
two of the N electrodes are arranged on each of the semiconductor pieces.

15. The protection diode of claim 11, wherein
the semiconductor layer and the N electrodes constitute N Schottky barriers, and
the N Schottky barriers are connected to one another in series.

16. A semiconductor device comprising:
a channel region on a substrate;
a gate structure on the channel region and comprising a gate dielectric, a gate electrode, and a gate capping film that are sequentially stacked, and further comprising gate spacers on sidewalls of the gate dielectric, the gate electrode, and the gate capping film, and a gate contact contacting the gate electrode;
source/drain regions on both sides of the channel region;
source/drain contacts electrically contacting the source/drain regions; and
a protection diode configured to protect the gate dielectric from a transient voltage,
wherein the protection diode comprises
a lower insulation film on the substrate,
a semiconductor layer on the lower insulation film such that the lower insulation film is between the semiconductor layer and the substrate,
a first electrode and a second electrode on the semiconductor layer such that the first electrode and the second electrode are horizontally spaced apart from each other and provide a Schottky contact, and
an interlayer insulation film on the semiconductor layer and surrounding the first electrode and the second electrode on the semiconductor layer, and
wherein the first electrode is electrically connected to the gate contact, and the second electrode is connected to a ground level or a certain DC level.

17. The semiconductor device of claim 16, wherein the semiconductor layer comprises at least one of InGaZnO, InGaO, InSnGaO, InZnO, or InSnZnO, and
the first electrode and the second electrode share the semiconductor layer.

18. The semiconductor device of claim 16, wherein the channel region comprises a material substantially identical to that constituting the semiconductor layer.

19. The semiconductor device of claim 16, wherein the semiconductor layer and the first electrode constitute a first Schottky barrier,
the semiconductor layer and the second electrode constitute a second Schottky barrier,
the first Schottky barrier and the second Schottky barrier are connected to each other in series, and
the Schottky contact includes the first Schottky barrier and the second Schottky barrier.

20. The semiconductor device of claim 16, further comprising:
a protection diode gate structure between the first electrode and the second electrode in a horizontal direction.
